(19) United States
(12) Patent Application Publication
(10) Pub. No.: US 2015/0303393 A1
(43) Pub. Date: Oct. 22, 2015

(54) ORGANIC ELECTROLUMINESCENT DEVICE AND PROCESS FOR PREPARING THE SAME

(71) Applicant: BOE Technology Group Co., Ltd, Beijing (CN)

(72) Inventors: Qing DAI, Beijing (CN); Ze LIU, Beijing (CN); Li SUN, Beijing (CN)

(21) Appl. No.: 14/342,246

(22) PCT Filed: Sep. 9, 2013
(86) PCT No.: PCT/CN2013/083144

§ 371 Date: Feb. 28, 2014

(30) Foreign Application Priority Data
Apr. 1, 2013 (CN) 201310110257.8

(51) Int. Cl. H01L 51/50; H01L 51/00; H01L 27/32; H01L 51/56

(52) U.S. Cl. CPC H01L 51/5012; H01L 51/56; H01L 51/0002; H01L 51/0017; H01L 27/3246

(57) ABSTRACT

An organic electroluminescent device and a process for preparing the organic electroluminescent device, wherein the organic electroluminescent device includes a substrate, on which pixel dividing walls are provided, said pixel dividing walls are composed of at least two stacked organic material dividing layers, and adjacent organic material dividing layers have different wettability. A process for preparing the organic electroluminescent device, including depositing and patternizing a bottom electrode; preparing two or more layers of pixel dividing walls; preparing a functional layer by deposition; and depositing sequentially a cathode, a protective layer and a sealing layer. The pixel dividing wall of the organic electroluminescent device are composed by stacking at least two organic material dividing layers, wherein the wettability of the adjacent organic material dividing layers is different, so as to ensure that a functional film with an even thickness is formed after ink droplets printed to a pixel region are dried. The organic material dividing layers have strong adhesion, thereby ensuring the good performance of the device.

### FIELD OF INVENTION

An embodiment of the invention relates to an organic electroluminescent device and a process for preparing the organic electroluminescent device.

### BACKGROUND OF INVENTION

Recently, as a novel flat panel display, the organic electroluminescent displays attract more and more attention. The organic electroluminescent display is characterized by lightness and thinness, wide visual angle, low energy consumption, rapid response, ability to achieve flexible display, and the like. Since it is an active light-emitting display device, it is deemed as having great advantages in displaying high resolution and high speed video, and in recent years, it has been developed toward more and more practicality. A key component of the organic electroluminescent display is the organic electroluminescent device.

The electroluminescent layer of the organic electroluminescent device (OLED) can be formed, generally, by small molecule materials and macromolecular (polymer) materials. Typically, it is known that the small molecule materials provide higher electroluminescent efficiency and have longer life. In particular, the small molecule materials provide a better performance for blue color.

Moreover, the processes for forming the organic film of the organic electroluminescent device currently include two large categories, wherein one relates to a dry process using techniques such as vacuum evaporation, and the other relates to a wet method process using various solutions, such as spin coating, inkjet printing, nozzle coating, and the like. The dry process typically applies to only small molecule materials, while the wet method process is generally used to prepare an electroluminescent layer of polymer materials. The advantage of the dry process is that no dissolution with solvent is required during the formation of the organic film, such that the process of removing the solvent after the formation of the film is avoided and usually the film has even thickness. However, they have the disadvantage of low utilization of materials which leads to severe waste of materials in large scale manufacture, and high requirements on devices, including high cost and the like. Therefore, the dry process does not apply to large scale manufacture or large size products. In contrast, the wet method process attracts wide attention due to their advantages in these two aspects.

As to the wet method process, how to control the shape of the organic film formed within the pixel region after the drying of the droplets that form functional layers (hereinafter “the droplets”) is difficult and critical for ensuring the performance of the organic electroluminescent device. Formation of a pixel film with even thickness is a necessity to ensure that the device has good efficiency and life. In order to achieve an even thickness of the organic material film within pixels, it usually requires that the pixel defining layer (that is, a wall structure dividing adjacent pixels, hereinafter referred to as “pixel dividing wall”) have some lyophilicity. Meanwhile, in order to precisely control a certain organic material solution or ink to enter a given pixel region, it usually requires that said pixel dividing wall have lyophobicity so that even if a few droplets fall on the wall body of the pixel dividing wall during preparing, they will flow into the pixel slot due to their lyophobicity. Therefore, it is a difficulty to control the droplets to precisely drop into the given pixel region and meanwhile ensure that the droplets dropped into the pixel result in a film with even thickness after drying.

In order to resolve the aforesaid problems, researchers have proposed the following solutions. In a first method, the pixel dividing wall is designed as a structure of two layers, with a first layer (that is, the bottom layer) being a lyophilic inorganic material, while a second layer above the first layer being a lyophobic organic material. In a second method, the pixel dividing wall is designed as an inorganic material pixel dividing wall having a structure of two or more layers, where the level of wettability is adjusted by controlling the rate of the film deposition. Although the aforesaid two solutions can advantageously improve the position precision of the dropping of droplets and the evenness of the film thickness after drying in the wet method processes for OLED, the processes for preparing the pixel dividing wall in these protocols still have the following deficiencies:

(1) For the mixed pixel dividing wall system composed of inorganic and organic materials in the first method, there are usually great differences in the method and process for preparing the two films and the resulting hardware devices are also distinct. Therefore, there are high requirement for the input of the hardware devices which will thus lead to higher actual production cost.

Moreover, the adhesive force between an inorganic layer and an organic layer is generally weak, making it easy for the separation between the inorganic and organic layers under external forces or when bending, causing the reduction of properties of the device.

(2) For the inorganic material film in the second method, it is usually prepared employing chemical vapor deposition, physical vapor deposition, atomic layer deposition, evaporation or the like, wherein the preparing processes all require specific reactive gases (usually toxic gases) and high energy consumption. Moreover, these processes are generally applicable only under a certain degree of vacuum, leading to higher requirements on the investment and performance of the devices.

### SUMMARY OF INVENTION

An embodiment of the invention provides an organic electroluminescent device, which comprises a substrate, on which multiple pixel dividing walls and multiple pixels divided by the multiple pixel dividing walls are provided, wherein said pixel dividing walls are composed of at least two stacked organic material dividing layers, and adjacent organic material dividing layers have different wettability.

In the organic electroluminescent device of the embodiment of the invention, the pixel dividing wall comprises a lyophilic organic material dividing layer and a lyophobic organic material dividing layer.

In the organic electroluminescent device of the embodiment of the invention, the pixel dividing wall is formed by alternately stacking multiple lyophilic organic material dividing layers and multiple lyophobic organic material dividing layers.

In the organic electroluminescent device of the embodiment of the invention, the pixel dividing wall has a lyophobic organic material dividing layer at the top, and a lyophilic organic material dividing layer at the bottom.

In the organic electroluminescent device of the embodiment of the invention, the organic material dividing layer of the pixel dividing wall is formed from a material which comprises a polymer material.

In the organic electroluminescent device of the embodiment of the invention, the material which forms the organic material dividing layer of the pixel dividing wall comprises a light sensitive polymer material.

In the organic electroluminescent device of the embodiment of the invention, a material which forms the lyophilic organic material dividing layer is formed by a material which comprises a polymer material having a polar group.

In the organic electroluminescent device of the embodiment of the invention, the material which forms the lyophilic organic material dividing layer comprises a polymer material containing a polar group of hydroxy, sulfydryl, amino, carboxy, amido, or the like.

In the organic electroluminescent device of the embodiment of the invention, the material which forms the lyophilic organic material dividing layer comprises one or more of polyhydroxystyrene derivatives, phenolic resin derivatives, poly(meth)acrylate derivatives, polyhydroxyethyl(meth)acrylate derivatives, polyvinyl alcohol derivatives, polycinnamate derivatives, polyimides, and polymaleic anhydrides.

In the organic electroluminescent device of the embodiment of the invention, the lyophobic organic material dividing layer is formed from a material which comprises a fully or partially fluorinated polymer material.

In the organic electroluminescent device of the embodiment of the invention, the fully or partially fluorinated polymer material comprises one or more of fluorinated polyacrylates or polymethacrylates, fluorinated polyimide derivatives, fluorinated siloxane derivatives, fluorinated norbornene dicarboxylic anhydride derivatives, fluorinated maleic anhydride derivatives, and fluorinated epoxide derivatives.

In the organic electroluminescent device of the embodiment of the invention, the pixel comprises:

an anode on the substrate;

a functional layer on the anode, the functional layer having a multi-layered structure; and

a cathode on the functional layer,

wherein the functional layer in the pixel has a bottom layer, wherein a sum of a thickness of the bottom layer plus a thickness of the anode is equal to or approximately equal to a thickness of the lyophilic organic material dividing layer at the bottom of the pixel dividing wall, and a thickness of each of other layers in the functional layer in the pixel is equal to or approximately equal to a sum of a thickness of the lyophilic organic material dividing layer positioned in an upper portion of the pixel dividing wall and a thickness of the lyophobic organic material dividing layer positioned in a lower portion of the pixel dividing wall adjacent to this layer of the functional layer.

An embodiment of the invention provides a process for preparing an organic electroluminescent device, comprising the steps of:

(1) depositing and patternizing a bottom electrode on a substrate containing a driver transistor; and

(2) forming multiple layers of a pixel dividing wall on the aforesaid substrate deposited with the patternized bottom electrode by coating, the pixel dividing wall comprising a lyophilic organic material dividing layer(s) and a lyophobic organic material dividing layer(s) stacked alternatively;

(3) depositing a functional layer on a pixel region defined by the pixel dividing wall; and

(4) sequentially depositing a cathode, a protective layer and a sealing layer on the functional layer and pixel dividing wall.

The process for preparing the organic electroluminescent device of the embodiment of the invention comprises the steps of:

(1) forming a bottom layer of the pixel dividing wall on a substrate by coating, followed by drying or annealing the bottom layer; and

(2) sequentially forming other layers of the pixel dividing wall on the bottom layer by coating.

The process for preparing the organic electroluminescent device of the embodiment of the invention further comprises:

patternizing each organic material dividing layer after the formation of each of multiple organic material dividing layers of the pixel dividing wall.

The process for preparing the organic electroluminescent device of the embodiment of the invention further comprises:

patternizing all of multiple organic material dividing layers, after the formation of all of the multiple organic material dividing layers of the pixel dividing wall.

In the process for preparing the organic electroluminescent device of the embodiment of the invention, the patternizing is conducted using an exposure and development process and/or an etching process.

### DESCRIPTION OF DRAWINGS

FIG. 1 is a structural diagram of an organic electroluminescent device having two layers of pixel dividing walls.

FIG. 2 is a structural diagram of an organic electroluminescent device having multiple layers of pixel dividing walls.

FIG. 3 is a flow chart of a process for preparing the organic electroluminescent device according to one embodiment of the invention.

FIG. 4 is a diagram of the flow chart for an embodiment of a process for forming two layers of pixel dividing wall in FIG. 3.

FIG. 5 is a diagram of the flow chart for an embodiment of a process for forming multiple layers of pixel dividing wall in FIG. 3.

### DETAILED DESCRIPTION OF INVENTION

Aiming at the deficiencies still existing in the composition and preparation of the pixel dividing wall in the prior art, we provide in the present application a pixel dividing wall with the following composition and structure, which is characterized by the following aspects:

(1) The pixel dividing wall is formed by two or more stacked organic material dividing layers, wherein the dividing layer may be made from polymer material.

(2) The thickness of the dividing layer can be adjusted according to the thickness of each layer of functional film deposited within the pixel region to achieve the best match for the performance of the device.

(3) The wettability of the surfaces of the adjacent two organic material dividing layers to a solvent is significantly different, that is, the lyophilic layer and the lyophobic layer are arranged alternatively. Generally, the bottom layer is a lyophilic layer while the top layer is a lyophobic layer.

(4) The pixel dividing wall is manufactured by a process different from that for preparing an inorganic pixel dividing wall, usually by way of a wet method process, such as spin coating, nozzle coating, knife coating, printing, and the like. In such a process, the re-dissolution of coated film of the lower layer by the upper layer can be avoided. To this end, the following solution can be employed: the solvents useful for the two adjacent layers should have great difference in polarity and are preferably not miscible, or alternatively, the material of lower layer in the adjacent layers is first subjected to a curing or cross-linking process after coating, so that it cannot be dissolved by the subsequent coating solvent.

The structure of the pixel dividing wall of the embodiment of the invention can achieve the following effect. Firstly, designing the top layer as a lyophobic layer structure can ensure that the droplets of the material to form the functional layer are precisely dropped into the desired pixel region, and its lyophobicity prevents the liquid from climbing up along the internal side of the pixel dividing wall during a drying process due to too high wettability, effectively avoiding short circuit of the upper layer electrode and electric leakage among pixels. Secondly, the lyophilicity of the lower film, that is, a relatively high wettability to an ink material, can effectively prevent organic material solutions from repelling each other during drying, reducing the tendency of variation among thickness of the organic film, that is, resulting in a relatively smooth film. The two aspects can both effectively improve the ultimate performance and life of the organic electroluminescent device. Moreover, the pixel dividing wall of multi-layered organic polymers in the embodiment of the invention is formed by a film-forming process, that is, a wet method process, different from that with an inorganic material. A wet coating process has the following advantages:

(1) both of the utility and film-forming efficiency of the materials are high, thereby facilitating the reduction of cost;

(2) the wet coating process is usually conducted under an atmospheric environment, leading to lower requirements on devices and process conditions, as compared to vapor deposition;

(3) The materials of the two layers have good compatibility and are not prone to stripping from each other;

(4) the organic materials may be selected from a wider scope, and can be surface modified and adjusted according to the requirement on wettability, as compared to inorganic materials; and

(5) Choosing an organic material can simplify the process for preparing the pixel defining layer, especially where the polymer is a photoactive material (having light sensitivity), which upon forming a film, can be subjected to a one-step exposure and development process to form a pattern. Moreover, the steps for preparing and removing a photoresist protective layer during patternization can be omitted and thus reduce the production cost, as compared to the process for preparing an inorganic pixel dividing wall.

An embodiment of the invention provides an organic electroluminescent device, which comprises a substrate, on which multiple pixel dividing walls and multiple pixels divided by the multiple pixel dividing walls are provided, wherein said pixel dividing walls are composed of at least two stacked organic material dividing layers, and adjacent organic material dividing layers have different wettability.

In the organic electroluminescent device of the embodiment of the invention, the pixel dividing wall comprises a lyophilic organic material dividing layer and a lyophobic organic material dividing layer.

In the organic electroluminescent device of the embodiment of the invention, the pixel dividing wall is formed by alternately stacking multiple lyophilic organic material dividing layers and multiple lyophobic organic material dividing layers.

In the organic electroluminescent device of the embodiment of the invention, the pixel dividing wall has a lyophobic organic material dividing layer at the top, and a lyophilic organic material dividing layer at the bottom.

In the organic electroluminescent device of the embodiment of the invention, the organic material dividing layer of the pixel dividing wall is formed from a material which comprises a polymer material.

In the organic electroluminescent device of the embodiment of the invention, the material which forms the organic material dividing layer of the pixel dividing wall comprises a light sensitive polymer material.

In the organic electroluminescent device of the embodiment of the invention, a material which forms the lyophilic organic material dividing layer is formed by a material which comprises a polymer material having a polar group.

In the organic electroluminescent device of the embodiment of the invention, the material which forms the lyophilic organic material dividing layer comprises a polymer material containing a polar group of hydroxy, sulfydryl, amino, carboxy, amido, or the like.

In the organic electroluminescent device of the embodiment of the invention, the material which forms the lyophilic organic material dividing layer comprises one or more of polyhydroxystyrene derivatives, phenolic resin derivatives, poly(meth)acrylate derivatives, polyhydroxyethyl(meth)acrylate derivatives, polyvinyl alcohol derivatives, polycinnamate derivatives, polyimides, and polymaleic anhydrides.

In the organic electroluminescent device of the embodiment of the invention, the lyophobic organic material dividing layer is formed from a material which comprises a fully or partially fluorinated polymer material.

In the organic electroluminescent device of the embodiment of the invention, the fully or partially fluorinated polymer material comprises one or more of fluorinated polyacrylates or polymethacrylates, fluorinated polyimide derivatives, fluorinated siloxane derivatives, fluorinated norbornene dicarboxylic anhydride derivatives, fluorinated maleic anhydride derivatives, and fluorinated epoxide derivatives.

In the organic electroluminescent device of the embodiment of the invention, the pixel comprises:

an anode on the substrate;

a functional layer on the anode, the functional layer having a multi-layered structure; and

a cathode on the functional layer,

wherein the functional layer in the pixel has a bottom layer, wherein a sum of a thickness of the bottom layer plus a thickness of the anode is equal to or approximately equal to a thickness of the lyophilic organic material dividing layer at the bottom of the pixel dividing wall, and a thickness of each of other layers in the functional layer in the pixel is equal to or approximately equal to a sum of a thickness of the lyophilic organic material dividing layer positioned in an upper portion of the pixel dividing wall and a thickness of the lyophobic organic material dividing layer positioned in a lower portion of the pixel dividing wall adjacent to this layer of the functional layer.

The functional layer comprises all or at least some of a hole injection layer, a hole transport layer, a light emitting layer, an electron transport layer and an electron injection layer, and at least comprises a light emitting layer.

An embodiment of the invention provides a process for preparing an organic electroluminescent device, comprising the steps of:

(1) depositing and patternizing a bottom electrode on a substrate containing a driver transistor; and

(2) forming multiple layers of a pixel dividing wall on the aforesaid substrate deposited with the patternized bottom electrode by coating, the pixel dividing wall comprising a lyophilic organic material dividing layer(s) and a lyophobic organic material dividing layer(s) stacked alternatively;

(3) depositing a functional layer on a pixel region defined by the pixel dividing wall; and

(4) sequentially depositing a cathode, a protective layer and a sealing layer on the functional layer and pixel dividing wall.

The process for preparing the organic electroluminescent device of the embodiment of the invention comprises the steps of:

(1) forming a bottom layer of the pixel dividing wall on a substrate by coating, followed by drying or annealing the bottom layer; and

(2) forming other layers of the pixel dividing wall on the bottom layer by coating.

The process for preparing the organic electroluminescent device of the embodiment of the invention further comprises:

patternizing each organic material dividing layer after the formation of each of multiple organic material dividing layers of the pixel dividing wall.

The process for preparing the organic electroluminescent device of the embodiment of the invention further comprises:

patternizing all of multiple organic material dividing layers, after the formation of all of the multiple organic material dividing layers of the pixel dividing wall.

In the process for preparing the organic electroluminescent device of the embodiment of the invention, the patternizing is conducted using an exposure and development process and/or an etching process.

The invention is further illustrated below in reference to specific examples. However, the invention is not limited to the following examples.

### Example 1

### An Organic Electroluminescent Device with Two Layers of Pixel Dividing Walls

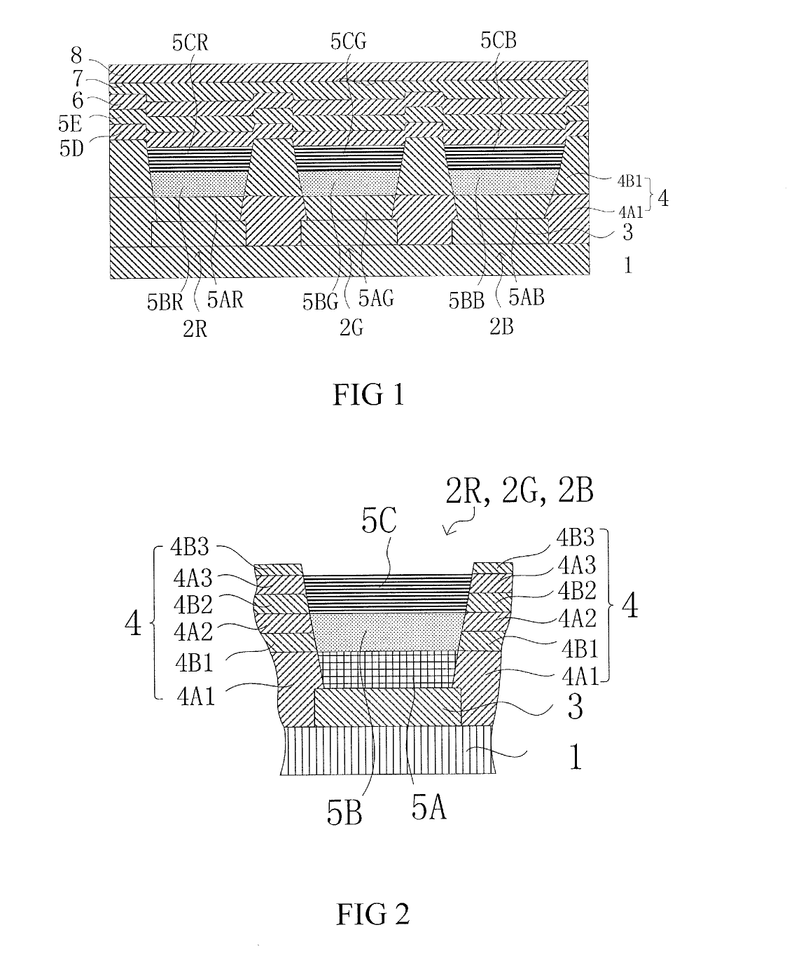

FIG. 1 shows a cross section of an example of an organic electroluminescent device of the invention. The organic electroluminescent device consists of the following components: substrate 1 (loaded with electroluminescent units 2R, 2G, and 2B), and bottom electrode 3 (referring to anode in this Example), pixel dividing wall 4 (first dividing layer 4A1 and second dividing layer 4B1), hole injection layer 5A (comprising 5AR, 5AG, and 5AB), hole transport layer 5B (comprising 5BR, 5BG, and 5BB), light emitting layer (or luminescent layer) 5C (comprising 5CR, 5CG, and 5CB), electron transport layer 5D, electron injection layer 5E, top electrode 6 as a cathode, protective layer 7 and sealing substrate 8 sequentially deposited on the substrate.

Substrate 1 is primarily loaded with a red organic electroluminescent unit 2R, a green organic electroluminescent unit 2G and a blue organic electroluminescent unit 2B. The material useful for the substrate may be quartz, glass, metal, resin and the like, preferably glass and quartz. The resin includes but is not limited to polymethyl (meth)acrylate (PMMA), polyethylene terephthalate (PET), polyethylene naphthalate (PBN), and polycarbonate resin. The substrate should have good impedance to water and gas, while for a bottom emission device, the substrate should further have good transparency, that is, light within a visible wavelength range can transmit through the substrate.

The bottom electrode 3 is disposed on the substrate 1, serving as the anode of the red organic electroluminescent unit 2R, the green organic electroluminescent unit 2G and the blue organic electroluminescent unit 2B, respectively. The composition of the bottom electrode may include an elementary substance of a metal, such as chromium (Cr), gold (Au), platinum (Pt), nickel (Ni), copper (Cu), tungsten (W), aluminum (Al), as well as silver, and the like, or the alloys thereof. The metal element may be selected from, but is not limited to, the aforesaid metals. The bottom electrode 3 is formed from a film made from an elementary substance, alloys, or oxides of the aforesaid metal elements, for example, a transparent conductive film composed of indium tin oxide (ITO), indium zinc oxide (InZnO), or zinc oxide (ZnO).

The pixel dividing wall 4 is used to define the shape and size of the light emitting region, and to ensure an insulation between the bottom electrode 3 and the top electrode 6. In addition, for a wet process, such as using an inkjet printing or nozzle coating method, the pixel dividing wall 4 may further ensure that the droplets (that is, the materials forming the functional layer) can be effectively dropped into the pixel region (avoiding color contamination and short circuit between pixels) and that the thickness of the functional film within the pixel after the drying of the droplets is as even as possible. In order to achieve the first purpose mentioned above, the upper surface of the pixel dividing wall is required to have a lyophobic property, thereby the droplets containing functional material dropped on the upper surface of the pixel dividing wall will flow into the groove of the pixel region due to repulsive effect. Moreover, in order to ensure the evenness of the thickness of the functional film within the pixel region after drying, the internal surface of the pixel dividing wall 4 should have certain wettability to the droplet. If the wettability of the internal surface of the pixel dividing wall 4 to the droplets is too good, the liquid will climb up along the internal side of the pixel dividing wall, causing the thickness of the edges of the functional film significantly larger than the thickness of its center after drying; whereas if the wettability of the internal surface of the pixel dividing wall 4 to the droplets is too poor (that is, strong lyophobicity), the dried functional film will exhibit unevenness that is thick in the center and thin around the edges due to repulsive effect, even leading to an unfilled crevices where the functional film is in contact with the inner wall. The aforesaid two uneven situations both may lead to short circuit between the top electrode and the bottom electrode of the device, greatly compromising the performance of the device. Therefore, the pixel dividing wall poses certain requirements on the wettability of the liquid that forms the functional film (as measured by contact angle), and especially for an organic electroluminescent device manufactured by a fully wet process, solvents for the materials in each of the functional layers have different wettability to the pixel dividing wall. In such cases, a single layer of pixel dividing wall may not meet the requirement. Therefore, in the example of the invention, we dev a two-layered pixel dividing wall, that is, the pixel dividing wall comprises two dividing layers both of which are manufactured using organic materials. There is a significant difference in wettability between the two dividing layers, that is, one layer is composed of a material with higher lyophilicity (a lyophilic organic material dividing layer) 4A1, whereas the other layer is composed of a material with lower lyophilicity (or lyophobicity) (a lyophobic organic material dividing layer) 4B1. Moreover, the lyophilic organic material dividing layer 4A1 is at the bottom and the lyophobic organic material dividing layer 4B1 is at the top of the pixed dividing wall. Such structural design not only fully utilizes the lyophobic effect of the lyophobic organic material dividing layer 4B 1 in the pixel dividing wall to lead the falling droplets precisely into the pixel region, thereby preventing color contamination and short circuit between pixels, but also allows good wettability occurring between the lyophilic organic material dividing layer 4A1 at the bottom of the pixel dividing wall and a liquid that forms the hole injection layer 5A to effectively ensure that the liquid expands and forms a good film of hole injection layer 5A. The material useful for the lyophilic organic material dividing layer 4A1 may be selected from polymers with a polar group such as hydroxy, sulfydryl, amino, carboxy, amino, and the like. Examples of such a lyophilic polymer comprises but are not limited to polyhydroxystyrene derivatives, phenolic resin derivatives, poly(meth)acrylate derivatives, polyhydroxyethyl(meth)acrylate derivative, polyvinyl alcohol derivatives, polycinnamate derivatives, polyimides, polymaleic anhydrides, and the like. The material useful for the lyophobic organic material dividing layer 4B1 comprises but is not limited to a fluorinated or partially fluorinated polymer material. Such materials generally have low surface energy and thus low wettability to solvent. Examples of such materials comprise fluorinated polyacrylates or polymethacrylates, fluorinated polyimide derivatives, fluorinated siloxane derivatives, fluorinated norbornene dicarboxylic anhydride derivatives, fluorinated maleic anhydride derivatives, fluorinated epoxide derivatives, and the like. The selection of the polymer is not limited to those mentioned above.

The pixel dividing wall 4 is provided with a pixel opening corresponding to the light emitting region. The organic layer 5 (functional layer) and the top electrode 6 can be disposed not only in the opening, but also on the pixel dividing wall 4. However, only a portion corresponding to the opening emits light.

The functional layer 5R of the red organic electroluminescent unit 2R comprises a hole injection layer 5AR, a hole transport layer 5BR, a red light emitting layer 5CR, an electron transport layer 5D, and an electron injection layer 5E, which are stacked sequentially from the bottom electrode 3. The functional layer 5G of the green organic electroluminescent unit 2G comprises a hole injection layer 5AG, a hole transport layer 5BG, a green light emitting layer 5CG, an electron transport layer 5D, and an electron injection layer 5E, which are stacked sequentially from the bottom electrode 3. The functional layer 5B of the blue organic electroluminescent unit 2B comprises a hole injection layer 5AB, a hole transport layer 5BB, a red light emitting layer 5CB, an electron transport layer 5D, and an electron injection layer 5E, which are stacked sequentially from the bottom electrode 3.

The hole injection layers 5AR, 5AG and 5AB are used to improve the injection capability of holes and may modify the anode surface so as to serve as a buffering layer. The thickness of the hole injection layer may be 5 nm-100 nm, and preferably 8 nm-50 nm.

The thickness of the hole transport layer 5BR, 5BG and 5BB depends on the overall structure of the device, but their preferred thickness is 10 nm-200 nm, more preferably 15-150 nm. Examples for the polymer materials that form the hole transport layer comprises a luminescent material soluble in an organic solvent, such as polyvinyl carbozole and derivatives thereof, polyfluorene and derivatives thereof, polyaniline and derivatives thereof, polysilane and derivatives thereof, polysiloxane derivatives having arylamine structure in the backbone or pendant chain, polythiophene and derivatives thereof as well as polypyrrole and derivatives thereof, and the like. The hole transport layers 5BR, 5BG, and 5BB can be selected from, but are not limited to, those mentioned above. The polymer that forms the hole transport layer has a weight average molecular weight (Mw) of, for example, 50,000 to 300,000, preferably 100,000 to 200,000.

The luminescent layers 5CR, 5CG and 5CB are regions where holes and electrons are complexed to form excitons under the effect of an electric field. The thickness of the luminescent layer depends on the requirement on the overall property of the device, but preferably, the thickness being 10-200 nm, more preferably 15 nm-100 nm. The materials that form the red luminescent layer 5CR, the green luminescent layer 5CG and the blue luminescent layer 5CB may be either a small molecule or a polymeric material. As to a small molecule system, the luminescent layer may be manufactured by either an evaporation method or a solution method. For the solution method, the small molecule usually emits light as a guest, for example, doped into a polymer host. The polymer is generally prepared using a solution method due to its own property. Examples of luminescent polymers comprise polyfluorene and derivatives thereof, poly(p-phenylene vinylene) derivatives, polyphenylene derivatives, polyvinyl carbozole derivatives, and polythiophene derivatives. Examples of the small molecule luminescent materials comprise perylene pigments, coumarin pigments, rhodamine pigments, fluorescein pigments, pyrene, anthracene and derivatives thereof, diene or polyene derivatives, and the like. Moreover, the materials obtained by doping an organic electroluminescent material into the aforesaid polymer, such as those obtained by doping rubrene, perylene, 9,10-diphenylanthracene, tetraphenylbutadiene, Nile red and coumarin are also contemplated within the scope of such luminescent materials. However, the above are merely examples of luminescent materials, but not limited thereto and the luminescent materials may be selected from the existing materials which have been disclosed or commercialized.

The electron transport layer 5D is used to improve the electron transport efficiency of the luminescent unit. Preferably, the electron transport layer 5D further has an ability to block holes. In this example, the electron transport layer is configured to be deposited on the red luminescent layer 5CR, the green luminescent layer 5CG and the blue luminescent layer 5CB as a common layer. Examples of the materials that may form the electron transport layer 5D comprise, but are not limited to quinoline, perylene, phenanthroline, stilbene, pyrimidine, trizole, oxazole, fullerene, oxdiazole as well as fluorenone or derivatives or metal complexes thereof.

The electron injection layer 5E which is used to improve the injection efficiency of the electron from the cathode is deposed between the electron transport layer 5D and the cathode. Examples of the materials that may form the electron injection layer comprise lithium oxide (Li₂O), lithium fluoride (LiF), and a complex oxide of cesium (Cs₂CO₃), as well as a mixture of an oxide/complex oxide thereof. The material useful for the electron injection layer 5E is not limited to those mentioned above. The materials that may form the electron injection layer further comprise an alkali earth metal such as calcium and barium, an alkali metal such as lithium and cesium, a metal with low work function (such as indium and magnesium), an oxide/complex oxide/fluoride of the aforesaid metal elements, or an alloy thereof.

The top electrode 6 is made from a conductive film having a thickness of 5-1000 nm and preferably 10-150 nm. The top electrode material comprises aluminum (Al), magnesium (Mg), calcium (Ca), sodium (Na), gold (Au), silver (Ag), copper (Cu), chromium (Cr), platinum (Pt), nickel (Ni) as well as an alloy thereof. The top electrode may also be formed from a film made from an elementary substance, an alloy, or an oxide of the aforesaid metal elements, such as an indium tin oxide (ITO), indium zinc oxide (InZnO), and zinc oxide (ZnO) conductive film.

The protective layer 7 having a thickness of 1 μm-3 μm may be made from an insulated material or a conductive material. Examples of insulated material, for example, may comprise an inorganic amorphous insulated material, such as amorphous silicon (α-Si), amorphous silicon carbide (α-SiC), amorphous silicon nitride (α-SiN), amorphous carbon (α-C), and silicon dioxide (SiO₂). The protective layer has good insulation to moisture and oxygen to achieve a good protective effect on the device.

The sealing substrate 8 is located on the top electrode 6 and protective layer 7 of the red organic electroluminescent unit 2R, the green organic electroluminescent unit 2G and the blue organic electroluminescent unit 2B. The sealing substrate 8 seals the organic electroluminescent device together with an adhesive layer (not shown). For a top emission organic electroluminescent device, the sealing substrate 8 is required to have excellent transmissivity.

### Example 2

### An Organic Electroluminescent Device Having a Multi-Layered Pixel Dividing Wall

FIG. 2 shows a diagram of the organic electroluminescent device of the multi-layered pixel dividing wall of the Example. The organic electroluminescent device of the Example is essentially the same as the organic electroluminescent device in Example 1, except that the pixel dividing wall 4 is composed of more than two (multiple) stacked dividing layers, each of which is made from an organic material and has different wettability from adjacent dividing layer. The same component is indicated by the same index and is not described in details in this example.

The example shows a pixel dividing wall structure having multiple layers, in which each layer of the pixel dividing wall (namely, 4A1, 4B1, 4A2, 4B2, 4A3 and 4B3 in the Example) is composed of an organic material, such as a polymer material. Adjacent dividing layers have large difference in wettability to a liquid. For example, the first dividing layer 4A1 (from the bottom electrode) is formed from a highly lyophilic material, and the second dividing layer 4B1 is formed from a material with low wettability (lyophobic), with lyophilic layer and lyophobic layer stacked alternatively upwards. The specific number of the layers can be determined according to actual performance of the device, but a requisite is that the top layer of the pixel dividing wall, i.e., the dividing 4B3 in this example be a lyophobic material, so as to ensure that the droplets falling on the pixel dividing wall can flow into the pixel region due to repulsive effect during the subsequent coating of the functional materials. The thickness of each of dividing layers (4A1, 4B1, 4A2, 4B2, 4A3 and 4B3) can be determined according to the overall performance of the device. For example, in a preferable embodiment, the sum of the thickness of the hole injection layer 5A as the bottom layer within the pixel and the bottom electrode 3 equals to or approximately equals to the thickness of the lyophilic dividing layer 4A1 as the bottom layer of the pixel dividing wall. The thickness of the hole transport layer 5B equals to or approximately equals to the sum of the thickness of the lyophobic dividing layer 4B 1 in a lower portion of the pixel dividing wall and the lyophilic dividing layer 4A2 in an upper portion of the pixel dividing wall. The thickness of the luminescent layer 5C equals to or approximately equals to the lyophobic dividing layer 4B2 in a lower portion of the pixel dividing wall and the lyophilic dividing layer 4A3 in an upper portion of the pixel dividing wall. The thickness of the lyophilic dividing layers 4A1, 4A2, 4A3 and lyophobic dividing layers 4B1, 4B2, 4B3 may be 5-150 nm.

Examples of lyophobic organic polymer materials comprise generally a fluorinated polymer material, and may be a fully fluorinated or partially fluorinated polymer, such as fluorinated polyacrylates or polymethacrylates, fluorinated polyimide derivatives, fluorinated siloxane derivatives, fluorinated norbornene dicarboxylic anhydride derivatives, fluorinated maleic anhydride derivatives, and fluorinated epoxide derivatives. In order to achieve better patternization, the fluorinated polymer may, for example, be a light sensitive polymer, which can be considered as a photoresist material. The lyophilic polymer may be selected from a polymer having a polar group comprising, for example, hydroxy, sulfydryl, amino, carboxy, amido, and the like. The lyophilic polymer may, for example, be a light sensitive polymer having such a polar group, which can be considered as a photoresist material. Examples of lyophilic polymers comprise polyhydroxystyrene derivatives, phenolic resin derivatives, poly(meth)acrylate derivatives, polyvinyl alcohol derivatives, polycinnamate derivatives, and the like. The lyophilic polymer may be selected from, but is not limited to those mentioned above, as long as the dividing layer formed by the lyophilic polymer has significantly different wettability to the liquid used in the manufacture of the pixel functional layer as compared to the adjacent dividing layers in the pixel dividing wall. Typically, the contact angle difference of the two adjacent organic material dividing layers against the liquid that forms each layers of the functional layer is between 20 to 90 degrees.

### Example 3

### A Process for Preparing the Aforesaid Organic Electroluminescent Device

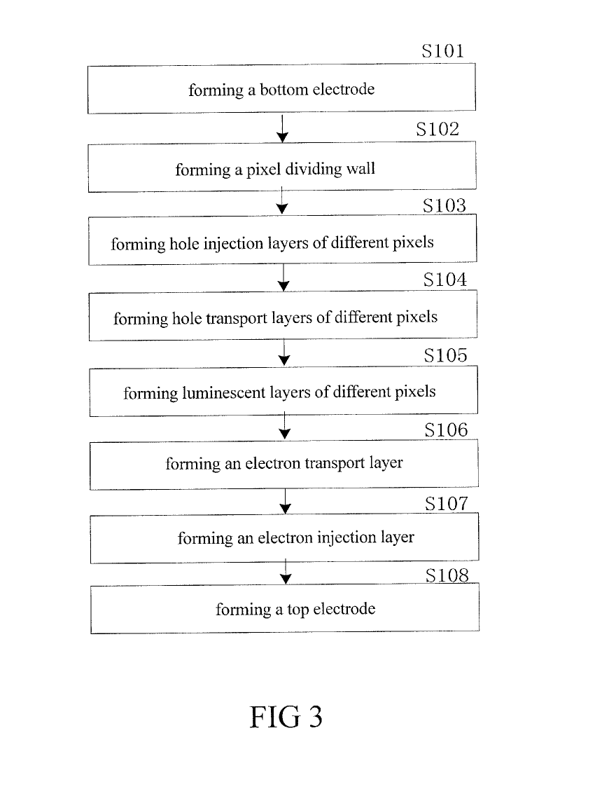

FIG. 3 shows a process for preparing an organic electroluminescent device comprising:

Step S101, forming a bottom electrode;

Step S102, forming a pixel dividing wall;

Step S103, forming hole injection layers of different pixels divided by pixel dividing walls;

Step S104, forming hole transport layers of different pixels divided by pixel dividing walls;

Step S105, forming luminescent layers of different pixels divided by pixel dividing walls;

Step S106, forming an electron transport layer;

Step S107, forming an electron injection layer; and

Step S108, forming a top electrode.

In conjunction with FIG. 2, firstly, a driver transistor of a pixel is formed on the substrate 1 made from the aforesaid materials, on which a planar insulation film which may be made from a light sensitive resin, is provided (not shown), and wherein a leak electrode of the driver transistor is connected to the bottom electrode 3 in the Example through a hole (not shown).

The Step for forming bottom electrode 3: A transparent conductive film, for example, made from ITO, is formed on substrate 1, and is patternized, forming multiple bottom electrodes which are each connected to a leak electrode of the driver transistor of different pixel (Step S101).

The Step for forming pixel dividing wall 4: Subsequently a layer of lyophilic polymer film is formed on the bottom electrode 3 and the planar insulation layer (not shown) by, for example, spin coating. The polymer film is patternized by exposure and development process (when such a polymer is a light sensitive polymer) or dry etching process (for polymers which are not light sensitive), forming a lyophilic organic material dividing layer 4A1 (first dividing layer) of the pixel dividing wall (Step S102). Below, as mentioned above, a lyophobic polymer film is formed on the first dividing layer 4A1 and the bottom electrode 3 by way of, for example, spin coating, and the polymer is patternized according to its properties to obtain a lyophobic organic material dividing layer 4B1 (second dividing layer) of the pixel dividing wall (Step S102). As such, each dividing layer film is made sequentially using a similar method and the lyophilic or lyophobic dividing layers 4A2, 4B2, 4A3 and 4B3, as well as other layers as required are formed using a pattern forming process. In particular, when an upper layer of dividing layer film is made by way of coating, the solvent used will not re-dissolve the already formed lower layer of dividing layer material. Moreover, for a pattern forming process useful for a pixel dividing wall composed by multiple stacked dividing layers, it can be optimized so that after all dividing layer films have been formed, only one pattern forming process, such as, exposure and development process and/or dry etching process, is employed, which may save cost.

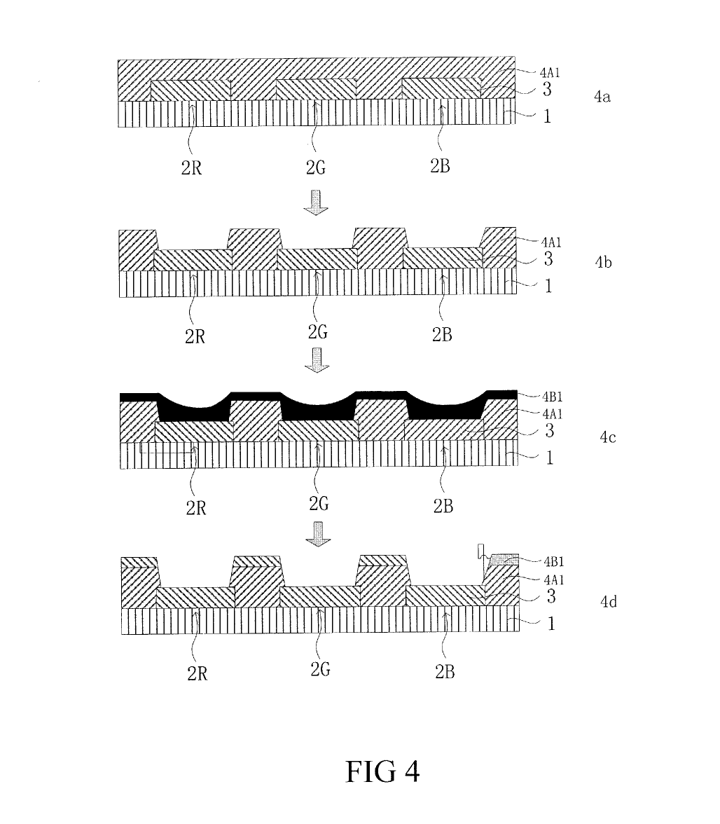

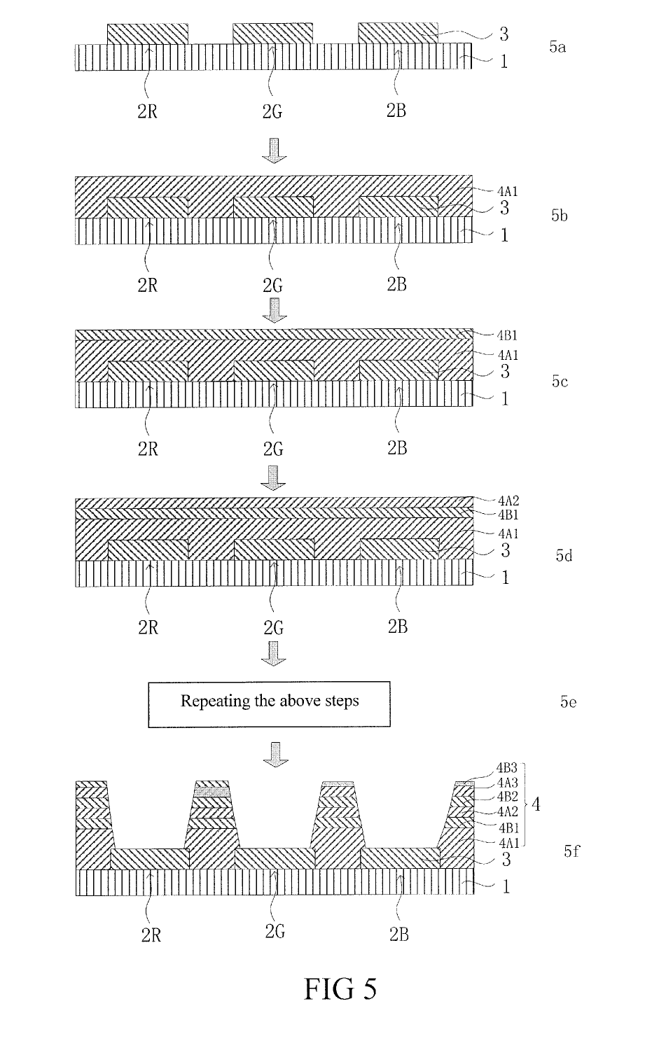

The Step for forming hole injection layers 5AR, 5AG, and 5AB: The hole injection layers (S103 in FIG. 4) are formed in the regions divided by the aforesaid pixel dividing walls. In particular, materials that may form the hole injection layers 5AR, 5AG and 5AB, such as polyaniline, polythiophene and the like in solution or other dispersion systems, are sprayed on the exposed surfaces of the bottom electrode 3 by inkjet printing. Then, the hole injection layers may be formed by heat treatment (drying treatment). The atmosphere and temperature for drying treatment are determined by the properties of the hole injection materials used.

The Step for forming hole transport layers 5BR, 5BG and 5BB: The hole injection layers are formed on the aforesaid hole injection layers in a manner similar to the hole injection layers, usually by way of coating. Because of the lyophobic effect on the top of the pixel dividing wall, it can be ensured that the droplets of the materials forming the hole transport layer can flow into the pixel region. Meanwhile, the structure of the pixel dividing wall is designed as the lyophilic dividing layers and the lyophobic dividing layers stacked alternatively. For example, due to the thickness sum of the prepared lyophobic dividing layer 4B 1 and lyophilic dividing layer 4A2 essentially equal to the thickness of the hole transport layer 5B required for the device, together with the effect of the lyophobic dividing layer 4B2, an even thickness of the hole transport layer 5B after drying can be ensured. During the drying treatment, the solvent is removed by heating, and the selection of the atmosphere is based on the properties of the material used, preferably nitrogen gas (N₂). For some systems, it may involve a crosslinking process with an oxygen gas, where an atmospheric condition is preferred. The heating temperature is preferably 150 to 300 degree Celsius, and more preferably 150 to 250 degree Celsius.

The step for forming organic luminescent layers 5CR, 5CG and 5CB: The red luminescent layer 5CR and the green luminescent layer 5CG are made on the hole transport layers 5BR and 5BG by way of coating. Subsequently, the inorganic solvent is removed by heat treatment to form an even film. The blue luminescent layer 5CB is prepared according to the material or the device structure employed. For a polymeric luminescent material, the film is generally formed by a solution method, such as coating. Due to the effect of the pixel dividing wall, solution droplets that contains the luminescent material can readily enter into the blue pixel region divided by the pixel dividing walls. For a small molecule blue luminescent material, the film is generally formed by evaporation deposition. The resulting film may be located only in the blue luminescent pixel unit, or may be located on all of the red luminescent layer, the green luminescent layer and the hole transport layer of the blue luminescent pixel unit as a continuous layer, depending on the requirement on the device structure.

The step for forming the electron transport layer 5D, the electron injection layer 5E and the top electrode 6: After the luminescent layer is formed, the electron transport layer 5D, the electron injection layer 5E and the top electrode 6 made from the aforesaid materials (Steps S106, S107 and S108 in FIG. 4) can be formed on top of the whole region by evaporation deposition.

After the top electrode is formed, the protective layer 7 made of the aforesaid materials is formed by evaporation deposition, chemical vapor deposition, or physical vapor deposition. During the formation of the protective layer 7, the energy of the film forming particles is small enough to pose almost no effect on the underlying organic electroluminescent units. Moreover, the film is compact sufficiently to resist the permeation of moisture and oxygen gas.

After the formation of the protective layer 7, the sealing substrate 8 and the protective layer are bound together with an adhesive (not shown) thereon. The organic electroluminescent device shown in FIG. 1 is now completed. Under a combined effect of the protective layer 7 and the sealing layer 8, the water vapor transmission rate (WVTR) may be reduced to a level less than 10⁻⁵ g/(m²·day).

### Example 4

### A Process for Preparing a Two-Layered Pixel Dividing Wall

General procedure for forming the pixel dividing wall 4 has been described in Example 3. It is more specifically exemplified below.

First, a poly(hydroxyethyl acrylate) solution is spin coated onto a substrate with a driver transistor and the bottom electrode (anode) 3, and followed by drying and annealing processes with gradient heating in an oven, to produce a poly(hydroxyethyl acrylate) film 4A1 (a lyophilic organic dividing layer film) (FIG. 4a). The resulting film is then subjected to exposure and development or other processing (mainly where the polymer used is a light sensitive polymer or contains a photoactive substance), resulting in a patternized first dividing layer 4A1 with exposed the bottom electrode 3 and serves as the pixel dividing wall (FIG. 4b). Subsequently, a prepolymer solution comprising a lyophobic fluorinated polyimide is coated onto the substrate surface with the first dividing layer 4A1 and the bottom electrode 3 exposed following a process similar to that mentioned above. Drying is conducted by gradient heating in an oven to remove the solvent and initiate imidization, resulting in a fluorinated polyimide film (the lyophobic organic material dividing layer film) 4B1 (FIG. 4c). The patternization of the film can be conducted by the aforesaid exposure, development and/or etching process, eventually resulting in the required pixel dividing wall composed of two stacked organic material dividing layers, wherein a region defined by the pixel dividing walls is the pixel opening region (FIG. 4d).

As to the process of patternization and etching, a dry etching process, such as a plasma etching or reactive ion etching process, may be used. These processes are commonly used in the patternization in semiconductor processes and are described in prior documents.

### Example 5

### A Process for Preparing a Multi-Layered Pixel Dividing Wall

In aforesaid Example 4, a process for preparing a two-layered pixel dividing wall has been illustrated which employs a layer-by-layer patternization. This method involves some repetitive steps and is insufficient to exhibit the advantages of the present disclosure. Therefore, in this Example, a pixel dividing wall composed of multiple stacked organic material dividing layers is obtained by a layer-by-layer coating and a one-step patternization process.

First, a first polymer film (a lyophilic organic material dividing layer film), polymaleic anhydride derivative 4A1, is prepared on a substrate with a driver transistor and the bottom electrode 3 by spin coating (FIG. 5b), and then the solvent is removed by drying. Subsequently, a fluorinated polyimide prepolymer is coated on the first layer of polymer film (FIG. 5c), and drying is conducted by gradient heating in an oven to remove the solvent and initiate imidization, resulting in a lyophobic organic material dividing layer film 4B1. Then, the polymaleic anhydride derivative is coated onto the lyophobic organic material dividing layer film 4B1 and dried and cured as above to produce a lyophilic organic material dividing layer film 4A2. Next, a lyophobic organic material dividing layer film (fluorinated polyimide) 4B2 is formed on the lyophilic organic material dividing layer 4A2. As such, a lyophilic polymaleic anhydride derivative film 4A3, a lyophobic fluorinated polyimide film 4B3, and the like are formed sequentially as described above (see FIGS. 5d and 5e, respectively). Finally, a patternized pixel dividing wall 4 composed of multiple stacked organic material dividing layers with the pixel region anode exposed is obtained by a development after exposure process, or a etching process (FIG. 5f).

The aforesaid are merely preferable embodiments of the invention. It should be pointed out that multiple improvements and modifications can be made by a person of ordinary skill in the art without departing from the principles of the invention, while these improvements and modifications should also be considered as within the scope of the invention.

1. An organic electroluminescent device, which comprises a substrate, on which multiple pixel dividing walls and multiple pixels divided by the multiple pixel dividing walls are provided, wherein said pixel dividing walls are composed of at least two stacked organic material dividing layers, and adjacent organic material dividing layers have different wettability.

2. The organic electroluminescent device according to claim 1, wherein the pixel dividing wall comprises a lyophilic organic material dividing layer and a lyophobic organic material dividing layer.

3. The organic electroluminescent device according to claim 2, wherein the pixel dividing wall is formed by alternately stacking multiple lyophilic organic material dividing layers and multiple lyophobic organic material dividing layers.

4. The organic electroluminescent device according to claim 2, wherein the pixel dividing wall has a lyophobic organic material dividing layer at the top, and a lyophilic organic material dividing layer at the bottom.

5. The organic electroluminescent device according to claim 1, wherein the organic material dividing layer of the pixel dividing wall is formed from a material which comprises a polymer material.

6. The organic electroluminescent device according to claim 5, wherein the material which forms the organic material dividing layer of the pixel dividing wall comprises a light sensitive polymer material.

7. The organic electroluminescent device according to claim 2, wherein the lyophilic organic material dividing layer is formed by a material which comprises a polymer material having a polar group.

8. The organic electroluminescent device according to claim 7, wherein the material which forms the lyophilic organic material dividing layer comprises a polymer material containing a polar group of hydroxy, sulfydryl, amino, carboxy, amido, or the like.

9. The organic electroluminescent device according to claim 8, wherein the material which forms the lyophilic organic material dividing layer comprises one or more of polyhydroxystyrene derivatives, phenolic resin derivatives, poly(meth)acrylate derivatives, polyhydroxyethyl (meth)acrylate derivatives, polyvinyl alcohol derivatives, polycinnamate derivatives, polyimides, and polymaleic anhydrides.

10. The organic electroluminescent device according to claim 2, wherein the lyophobic organic material dividing layer is formed from a material which comprises a fully or partially fluorinated polymer material.

11. The organic electroluminescent device according to claim 10, wherein the fully or partially fluorinated polymer material comprises one or more of fluorinated polyacrylates or polymethacrylates, fluorinated polyimide derivatives, fluorinated siloxane derivatives, fluorinated norbornene dicarboxylic anhydride derivatives, fluorinated maleic anhydride derivatives, and fluorinated epoxide derivatives.

12. The organic electroluminescent device according to claim 3, wherein the pixel comprises:
an anode on the substrate;
a functional layer on the anode, the functional layer having a multi-layered structure; and
a cathode on the functional layer,
wherein the functional layer in the pixel has a bottom layer, wherein a sum of a thickness of the bottom layer plus a thickness of the anode is equal to or approximately equal to a thickness of the lyophilic organic material dividing layer at the bottom of the pixel dividing wall, and a thickness of each of other layers in the functional layer in the pixel is equal to or approximately equal to a sum of a thickness of the lyophilic organic material dividing layer positioned in an upper portion of the pixel dividing wall and a thickness of the lyophobic organic material dividing layer positioned in a lower portion of the pixel dividing wall adjacent to this layer of the functional layer.

13. A process for preparing an organic electroluminescent device, comprising the steps of:
(1) depositing and patternizing a bottom electrode on a substrate containing a driver transistor;
(2) forming multiple layers of a pixel dividing wall on the substrate deposited with the patternized bottom electrode by coating, the pixel dividing wall comprising a lyophilic organic material dividing layer(s) and a lyophobic organic material dividing layer(s) stacked alternatively;
(3) depositing a functional layer on a pixel region defined by the pixel dividing wall; and
(4) sequentially depositing a cathode, a protective layer and a sealing layer on the functional layer and pixel dividing wall.

14. The process for preparing an organic electroluminescent device according to claim 13, which comprises the steps of:
(1) forming a bottom layer of the pixel dividing wall on a substrate by coating, followed by drying or annealing the bottom layer; and
(2) sequentially forming other layers of the pixel dividing wall on the bottom layer by coating.

15. The process for preparing an organic electroluminescent device according to claim 14, which further comprises:
patternizing each organic material dividing layer after the formation of each of multiple organic material dividing layers of the pixel dividing wall.

16. The process for preparing an organic electroluminescent device according to claim 14, which further comprises:
patternizing all of multiple organic material dividing layers, after the formation of all of the multiple organic material dividing layers of the pixel dividing wall.

17. The process for preparing an organic electroluminescent device according to claim 15, wherein the patternizing is conducted using an exposure and development process and/or an etching process.

18. The process for preparing an organic electroluminescent device according to claim 16, wherein the patternizing is conducted using an exposure and development process and/or an etching process.
